(19) United States
(12) Patent Application Publication
(10) Pub. No.: US 2024/0371314 A1
(43) Pub. Date: Nov. 7, 2024

(54) COMMON CATHODE MICRO LED DISPLAY DEVICE

(71) Applicant: GIANTPLUS TECHNOLOGY CO., LTD., Miauli County (TW)

(72) Inventor: Wei-Yu CHEN, Miauli County (TW)

(73) Assignee: GIANTPLUS TECHNOLOGY CO., LTD., Miauli County (TW)

(21) Appl. No.: 18/366,670

(22) Filed: Aug. 7, 2023

(30) Foreign Application Priority Data
May 5, 2023 (TW) 112116887

(51) Int. Cl. G09G 3/32; H01L 27/15

(52) U.S. Cl. CPC G09G 3/32; H01L 27/156; G09G 2320/0223

(57) ABSTRACT

The present disclosure related to a common cathode micro led display with a driving circuit, a ground end, a plurality of LED units and a plurality switch units. The driving circuit connected to a plurality of transmission wires. One end of the plurality of LED units or one end of the plurality switch units is electronically connected to the plurality of transmission wires. The ground end is configured with a plurality of scan lines. Free ends formed by the plurality of LED units and the plurality switch units connected in series connect to the scan lines. A plurality of vertical conducted groups or a plurality of horizontal conducted groups are formed according to the switch units. A control unit is configured to drive the plurality of vertical conduction groups or the plurality of horizontal conduction groups. Therefore, the object to avoid voltage drop caused by the drive current is achieved.

### CROSS REFERENCE TO RELATED APPLICATION

This application claims the priority benefit of Taiwan Patent Application Serial Number 112116887, filed on May 5, 2023, the full disclosure of which is incorporated herein by reference.

### BACKGROUND

### Technical Field

This present disclosure relates to a LED display device, and more particularly to a common cathode micro led display device.

### Related Art

In general, the structure of common cathode LED display device usually comprises a driver and a ground terminal. The driver has an output terminal for connecting in series to the anodes of a plurality of light emitting diodes (LED). The ground terminal has a scan line connected to the cathodes of the LEDs and a plurality of switch units are disposed between the ground terminal and the scan lines.

By controlling these switch units to be turned on or turned off, the LEDs are correspondingly turned on or turned off. However, the series-connected LEDs have higher resistance and need to be driven by a large current, which result in the voltage drop of the ground terminal.

Therefore, it is desirous to overcome the technical problem of prior art.

### SUMMARY

The embodiment of the present disclosure provides a common cathode micro led display device, which can reduce the resistance of a ground end and achieve the object of avoiding the voltage drop problem caused by the driving current.

One embodiment of the present disclosure provides a common cathode micro led display device, which includes a driving circuit, a plurality of light emitting diode units and a ground end. The driving circuit is configured with a plurality of output ends and each of the plurality of output ends is configured with a transmission wire. Each of the plurality of light emitting diode units comprises a first end and a second end. The plurality of light emitting diode units are connected to a plurality of switch units. The number of the plurality of switch units corresponds to the number of the plurality of light emitting diode units and the plurality of switch units are configured between the first ends of the plurality of light emitting diode units and the transmission wires. The ground end is configured with a plurality of ground wires, the plurality of ground wires connect to the second ends of the plurality of light emitting diode units.

One embodiment of the present disclosure provides that each of the plurality of switch units is between the transmission wire and one of the plurality of LED units or between the ground wire and one of the plurality of LED units.

One embodiment of the present disclosure provides that a plurality of vertical conducted groups or a plurality of horizontal conducted groups are formed by the switch units.

One embodiment of the present disclosure provides that the plurality of vertical conducted groups or the plurality of horizontal conducted groups are driven by a control unit of the driving circuit or an external circuit to conduct the switch units and the plurality of LED units sequentially.

With the above structure, the vertical conducted groups or the horizontal conducted groups are formed by the switch units, and the vertical conducted groups or the horizontal conducted groups are driven by the control unit. Therefore, it is avoided to turn on all the LED units on the panel at the same time, the resistance value of the ground end is reduced to avoid the voltage drop problem caused by the driving current of the LED units.

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic diagram of a vertical conducted group circuit in a first embodiment of the present disclosure;

FIG. 2 is a schematic diagram of a horizontal conducted group circuit in the first embodiment of the present disclosure;

FIG. 3 is a schematic diagram of a vertical conducted group circuit in a second embodiment of the present disclosure; and

FIG. 4 is a schematic diagram of a horizontal conducted group circuit in the second embodiment of the present disclosure.

### DETAILED DESCRIPTION OF THE EMBODIMENTS

The present disclosure will now be described more fully hereinafter with reference to the accompanying drawings, in which exemplary embodiments of the disclosure are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

Certain terms are used throughout the description and following claims to refer to particular components. As one skilled in the art will appreciate, manufacturers may refer to a component by different names. This document does not intend to distinguish between components that differ in name but function. In the following description and in the claims, the terms “include/including” and “comprise/comprising” are used in an open-ended fashion, and thus should be interpreted as “including but not limited to”. “Substantial/substantially” means, within an acceptable error range, the person skilled in the art may solve the technical problem in a certain error range to achieve the basic technical effect.

The following description is of the best-contemplated mode of carrying out the disclosure. This description is made for the purpose of illustration of the general principles of the disclosure and should not be taken in a limiting sense. The scope of the disclosure is best determined by reference to the appended claims.

Moreover, the terms “include”, “contain”, and any variation thereof are intended to cover a non-exclusive inclusion. Therefore, a process, method, object, or device that comprises a series of elements not only include these elements, but also comprises other elements not specified expressly, or may include inherent elements of the process, method, object, or device. If no more limitations are made, an element limited by “include a/an . . . ” does not exclude other same elements existing in the process, the method, the article, or the device which comprises the element.

In the following embodiment, the same reference numerals are used to refer to the same or similar elements throughout the disclosure.

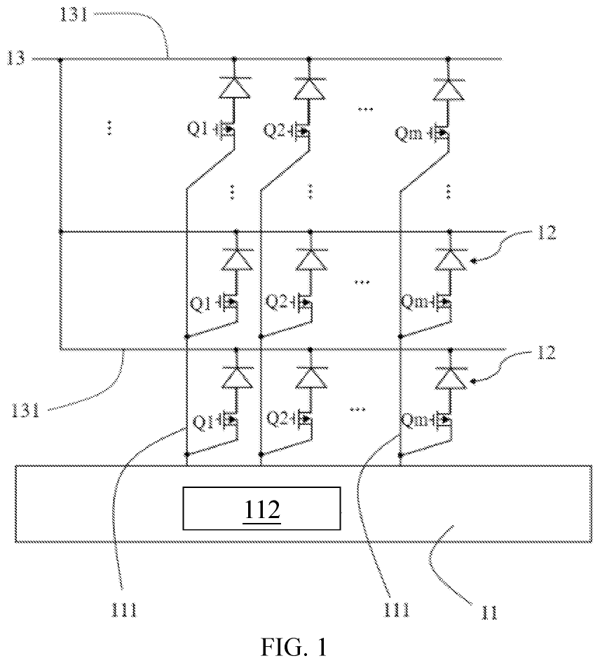

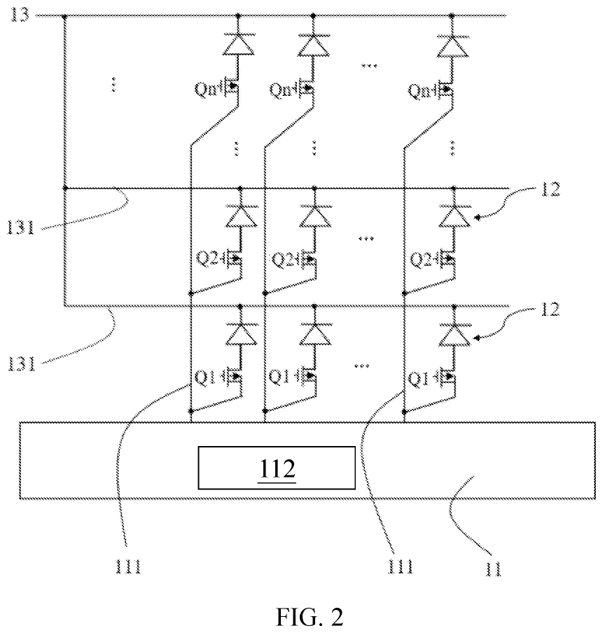

Regarding a first embodiment of the present disclosure, please refer to FIGS. 1 and 2, which include a driving circuit 11, a plurality of light emitting diode (Light-emitting diode, LED) units 12, a plurality of switching units Q1, Q2, Qn, Qm and a ground end 13.

The driving circuit 11 has a plurality of output ends, each output end is respectively configured with a transmission wire 111, and the voltage of each output end is higher than the voltage of the ground end 13 to form a relatively high potential voltage.

Each of the LED units 12 has a first end and a second end. The first end is defines as the anode and the second end is defines as the cathode. The LED units 12 are connected in series with a plurality of switch units Q1, Q2, Qn, Qm. In the embodiment of the present disclosure, the number of the switch units Q1, Q2, Qn, Qm is the same as the number of the LED units 12. Each of the switch units Q1, Q2, Qn, Qm is configured between one transmission wire 111 and the first end of one LED unit 12, so that each of the switch units Q1, Q2, Qn, Qm is electrically connected to the relatively high potential voltage. The ground end 13 is configured with a plurality of ground wires 131, and each of the ground wires 131 is connected to the second ends of the LED units 12.

A plurality of vertical conducted groups is formed by the switch units Q1, Q2, Qm between the transmission wires 111 and the LED units 12 when the LED units 12 and the switch units Q1, Q2, Qm are connected to the transmission wires 111. More specifically, as shown in FIG. 1, the switch unit marked as Q1 forms the first vertical conducted group, the switch unit marked as Q2 forms the second vertical conducted group, and the switch unit marked as Qm forms the mth vertical conduction group.

A plurality of horizontal conducted groups are formed by the switch units Q1, Q2, Qn between the transmission wires 111 and the LED units 12 when the LED units 12 and the switch units Q1, Q2, Qn are connected to the transmission wires 111. More specifically, as shown in FIG. 2, the switch unit marked as Q1 forms the first horizontal conducted group, the switch unit marked as Q2 forms the second horizontal conducted group, and the switch unit marked as Qn forms the nth horizontal conducted group.

The switch units Q1, Q2, Qn, Qm can be implemented by metal-oxide-semiconductor field-effect transistor (Metal-Oxide-Semiconductor Field-Effect Transistor) MOSFET. In this embodiment, the switching units Q1, Q2, Qn, and Qm are P-channel MOSFETs. Thus, the resistance value of the ground end 13 is reduced by connecting the plurality of ground wires 131 of the ground end 13 to the free ends of the LED units 12 and the switch units Q1, Q2, Qn, Qm connected in series. The voltage drop of the ground end caused by the driving current is avoided.

The drive circuit 11 or an external circuit (not shown) can be further provided with a control unit 112. The control unit 112 is used to drive the switch units Q1, Q2, Qn of the horizontal conducted groups or the switch units Q1, Q2, Qm of the vertical conducted groups. The switch units Q1, Q2, and Qm of the vertical conducted groups are driven by the control unit 112, so that the switch units marked as Q1, Q2 to Qm in FIG. 1 are sequentially conducted to achieve the effect of column-by-column conduction. Therefore, the present disclosure can achieve the effect of avoiding the voltage drop problem caused by the driving current by reducing the resistance value of the ground end 13 through column-by-column conduction. Similarly, the switch units Q1, Q2, and Qn of the horizontal conducted groups are driven by the control unit 112, so that the switch units marked as Q1, Q2 to Qn in FIG. 2 are sequentially conducted to achieve the effect of row-by-row conduction. Therefore, the present disclosure can achieve the effect of avoiding the voltage drop problem caused by the driving current by reducing the resistance value of the ground end 13 through row-by-row conduction.

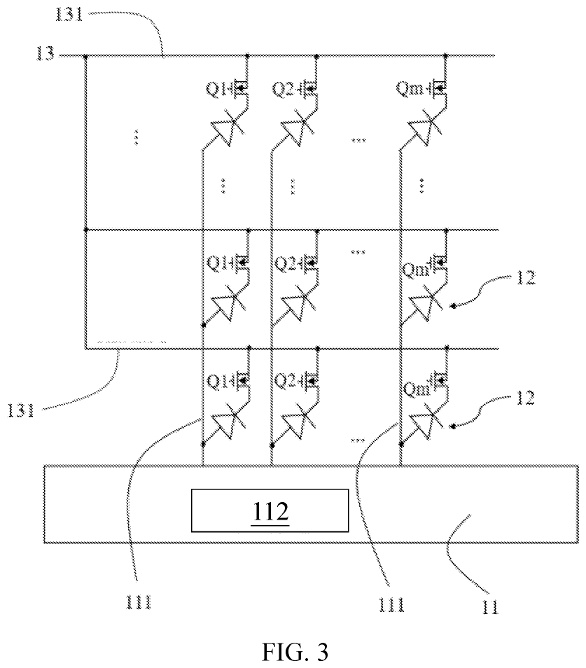

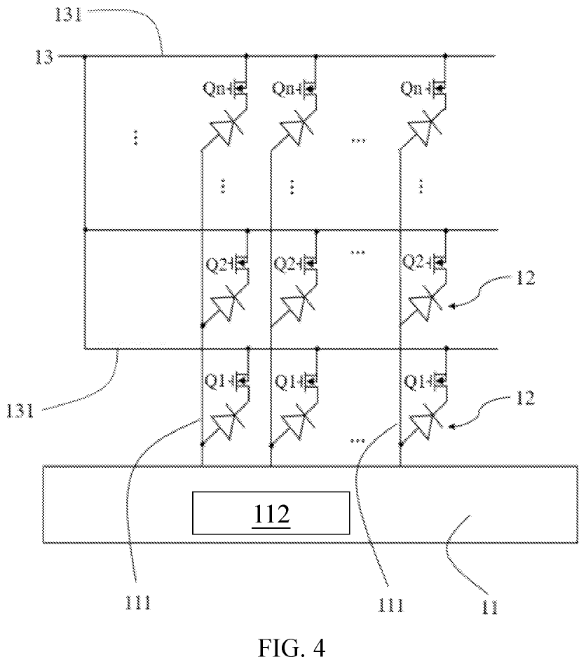

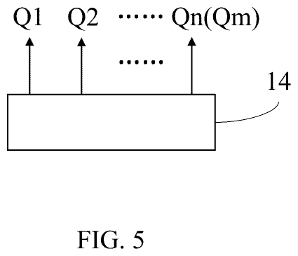

Regarding a second embodiment of the present disclosure, please refer to FIGS. 3 and 4, which include a driving circuit 11, a plurality of LED units 12, a plurality of switching units Q1, Q2, Qn, Qm and a ground end 13.

The driving circuit 11 has a plurality of output ends. Each output end is respectively configured with a transmission wire 111, and the voltage of each output end is higher than the voltage of the ground end 13 to form a relatively high potential voltage.

Each of the LED units 12 has a first end and a second end. The first end is defined as the anode and the second end is defined as the cathode. The LED units 12 are connected in series with a plurality of switch units Q1, Q2, Qn, Qm. In the embodiment of the present disclosure, the number of the switch units Q1, Q2, Qn, Qm is the same as the number of the LED units 12. The first ends of the LED units are disposed on and connected to the transmission wires 111 respectively. Each of the switch units Q1, Q2, Qn, Qm is configured between one ground wire 131 and the second end of one LED unit 12 and ground wires 131 are gathered and connected to ground end 13, so that each of the switch units Q1, Q2, Qn, Qm is electrically connected to the relatively high potential voltage.

A plurality of vertical conducted groups are formed by the switch units Q1, Q2, Qm between the transmission wires 111 and the LED units 12 when the LED units 12 and the switch units Q1, Q2, Qm are connected to the transmission wires 111. More specifically, as shown in FIG. 3, the switch unit marked as Q1 forms the first vertical conducted group, the switch unit marked as Q2 forms the second vertical conducted group, and the switch unit marked as Qm forms the mth vertical conduction group.

A plurality of horizontal conducted groups are formed by the switch units Q1, Q2, Qn between the transmission wires 111 and the LED units 12 when the LED units 12 and the switch units Q1, Q2, Qn are connected to the transmission wires 111. More specifically, as shown in FIG. 4, the switch unit marked as Q1 forms the first horizontal conducted group, the switch unit marked as Q2 forms the second horizontal conducted group, and the switch unit marked as Qn forms the nth horizontal conducted group.

The switch units Q1, Q2, Qn, Qm can be implemented by metal-oxide-semiconductor field-effect transistor (Metal-Oxide-Semiconductor Field-Effect Transistor) MOSFET. In this embodiment, the switching units Q1, Q2, Qn, and Qm are N-channel MOSFETs. Thus, the resistance value of the ground end 13 is reduced by connecting the plurality of ground wires 131 of the ground end 13 to the free ends of the LED units 12 and the switch units Q1, Q2, Qn, Qm connected in series. The voltage drop of the ground end 13 caused by the driving current is avoided.

The drive circuit 11 or an external circuit (not shown) can be further provided with a control unit 112. The control unit 112 is used to drive the switch units Q1, Q2, Qn of the horizontal conducted groups or the switch units Q1, Q2, Qm of the vertical conducted groups. Therefore, the present disclosure can achieve the effect of avoiding the voltage drop problem caused by the driving current by reducing the resistance value of the ground end 13 through column-by-column or row-by-row conduction. The operation of the control unit 112 is as described above, so it won't be repeated here.

It is to be understood that the term “comprises”, “comprising”, or any other variants thereof, is intended to encompass a non-exclusive inclusion, such that a process, method, article, or device of a series of elements not only include those elements but also comprises other elements that are not explicitly listed, or elements that are inherent to such a process, method, article, or device. An element defined by the phrase “comprising a . . . ” does not exclude the presence of the same element in the process, method, article, or device that comprises the element.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the disclosure. Accordingly, such modifications are considered within the scope of the disclosure as limited solely by the appended claims.

1. A common cathode micro light emitting diode display device, comprising:
a driving circuit configured with a plurality of output ends, each of the plurality of output ends configured with a transmission wire;
a plurality of light emitting diode units, each of the plurality of light emitting diode units comprising a first end and a second end, and the plurality of light emitting diode units connected to a plurality of switch units, wherein a number of the plurality of switch units corresponds to a number of the plurality of light emitting diode units, the plurality of switch units being configured between the first ends of the plurality of light emitting diode units and the transmission wires; and
a ground end configured with a plurality of ground wires, the plurality of ground wires connected to the second ends of the plurality of light emitting diode units;
wherein a plurality of vertical conducted groups are formed by the plurality of switch units between the transmission wires and the plurality of light emitting diode units when the plurality of light emitting diode units and the plurality of switch units are connected to the transmission wires, the plurality of switch units of the same vertical conducted group are connected to the same transmission wire, and the plurality of switch units of each of the plurality of vertical conducted groups are conducted or not conducted simultaneously.

2. (canceled)

3. The common cathode micro light emitting diode display device according to claim 1, wherein the driving circuit or an external circuit comprises a control unit that drives the plurality of switch units of the plurality of vertical conducted groups to conduct the plurality of light emitting diode units column by column.

4. (canceled)

5. (canceled)

6. A common cathode micro light emitting diode display device, comprising:
a driving circuit configured with a plurality of output ends, each of the plurality of output ends configured with a transmission wire;
a plurality of light emitting diode units, each of the light emitting diode units comprising a first end and a second end, and the plurality of light emitting diode units connected in series to a plurality of switch units, wherein a number of the plurality of switch units corresponds to a number of the plurality of light emitting diode units, the plurality of switch units being configured between the second ends of the plurality of light emitting diode units and a plurality of ground wires, and the first ends of the plurality of light emitting diode units are disposed on the transmission wires; and
a ground end, formed by the plurality of ground wires gathered together;
wherein a plurality of vertical conducted groups are formed by the plurality of switch units between the plurality of ground wires and the plurality of light emitting diode units when the plurality of light emitting diode units and the plurality of switch units are connected to the transmission wires, the plurality of light emitting diode units of the same vertical conducted group are connected to the same transmission wire, and the plurality of switch units of each of the plurality of vertical conducted groups are conducted or not conducted at same time.

7. (canceled)

8. The common cathode micro light emitting diode display device according to claim 6, wherein the driving circuit or an external circuit comprises a control unit that drives the plurality of switch units of the plurality of vertical conducted groups to conduct the plurality of light emitting diode units column by column.

9. (canceled)

10. (canceled)
